(19) United States
(12) Patent Application Publication
(10) Pub. No.: US 2025/0281868 A1
(43) Pub. Date: Sep. 11, 2025

(54) ABSORBER CANISTER FOR AN EXHAUST GAS ABATEMENT SYSTEM

(71) Applicant: Edwards Limited, Burgess Hill, Sussex (GB)

(72) Inventors: David Paul Manson, Burgess Hill, Sussex (GB); George Robert Whittell, Clevedon, Somerset (GB)

(21) Appl. No.: 18/857,346

(22) PCT Filed: Apr. 20, 2023
(86) PCT No.: PCT/GB2023/051032

§ 371 Date: Oct. 16, 2024

(30) Foreign Application Priority Data
Apr. 21, 2022 (GB) 2205829.1

(51) Int. Cl. B01D 53/04

(52) U.S. Cl. CPC B01D 53/0415; B01D 53/0446; B01D 2258/0216

(57) ABSTRACT

The present invention provides a dry absorber canister for an exhaust gas abatement system. The canister comprises a hollow chamber configured to retain particulate absorption media. The chamber having a cross-sectional area defined by a longitudinally extending wall, and the chamber having a gas inlet at a first end and a gas outlet at a second end. The cross-sectional area of the chamber varies between the first end and the second end. The cross-sectional area of the chamber increases from the gas inlet to a maximum cross-sectional area.

### CROSS-REFERENCE OF RELATED APPLICATION

This application is a Section 371 National Stage Application of International Application No. PCT/GB2023/051032, filed Apr. 20, 2023, and published as WO 2023/203329 A1 on Oct. 26, 2023, the content of which is hereby incorporated by reference in its entirety and which claims priority of British Application No. 2205829.1, filed Apr. 21, 2022.

### FIELD

The present invention relates to dry absorber canisters, exhaust gas abatement systems containing dry absorber canisters, and methods of abating an exhaust gas stream.

### BACKGROUND

In some industries, exhaust gas abatement systems may be used to treat exhaust gas from process equipment. This treatment may involve removing toxic and/or environmentally harmful substances present in the exhaust gas to render it harmless before its release into the atmosphere.

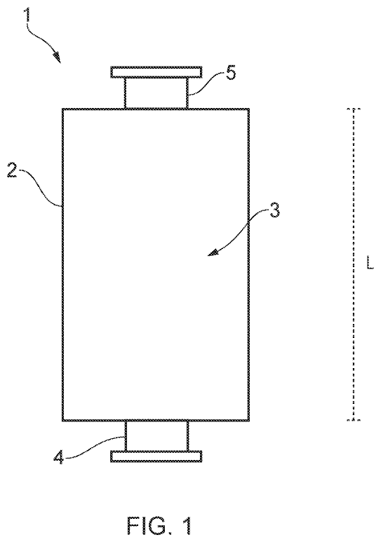

A “dry absorber canister” is an example of a component that may form part of a gas abatement system. FIG. 1 shows a cross-sectional view of a typical dry absorber canister (1) of the prior art. The canister (1) comprises a hollow chamber (3) defined by a cylindrical wall (2). The chamber (3) is filled with chemically active absorption media, for example basic copper(II) carbonate. The canister (1) comprises an inlet port (4) arranged at a first end, that is fluidly coupled to an outlet of the semiconductor processing equipment (not shown). The canister (1) further comprises an outlet port (5) arranged at a second end.

During operation, exhaust gas from the semiconductor manufacture process enters the canister (1) through the inlet port (4) and passes through the chamber (3), over the absorption media. Hazardous compounds in the exhaust gas, such as hydrogen chloride, passing through the chamber (3) react with the absorption media to form, for example, inert inorganic salts. Over time, the absorption media become deactivated and is no longer able to react with exhaust gas, and the canister (1) must be replaced.

The life-span of the canister (1) is limited by the deactivation rate of the absorption media contained therein. Accordingly, there is a desire to improve the efficiency of the abatement process to increase the life-span of the canister (1) before replacement is necessary.

The present invention aims to solve, at least in part, these and other problems associated with canisters of the prior art.

The discussion above is merely provided for general background information and is not intended to be used as an aid in determining the scope of the claimed subject matter. The claimed subject matter is not limited to implementations that solve any or all disadvantages noted in the background.

### SUMMARY

In an aspect, the present invention provides a dry absorber canister for an exhaust gas abatement system. The canister comprises a hollow chamber configured to retain particulate absorption media. The chamber has a cross-sectional area that is defined by a longitudinally extending wall, and has a gas inlet at a first end and a gas outlet at a second end. The cross-sectional area of the chamber varies between the first end and the second end, and the cross-sectional area of the chamber increases from the gas inlet to a maximum cross-sectional area.

Preferably, the dry absorber canister, or canister, may be for use in, or forms a part of, an exhaust gas abatement system of a semiconductor manufacturing process.

Typically, the dry absorber canister may include particulate absorption media retained within the chamber. Typically, the particulate absorption media may be solid particles or pellets. The particulate absorption media may comprise involatile inorganic salt(s), for example, copper(II) chloride. Typically, when in use, the particulate absorption media may be packed within the chamber such that the particulate absorption media are substantially immobilised therein. The skilled person will appreciate that there may be voids between the absorption media particles to allow the exhaust gas to flow therebetween. Preferably, each particle of the absorption media may have a minimum dimension of from about 1 mm to about 10 mm, preferably from about 2 mm to about 8 mm. For example, each particle of the absorption media may be generally cylindrical and have a diameter of from about 2 mm to about 8 mm.

In embodiments, the gas inlet may be connectable to a source of gas to be processed. The gas to be processed may comprise hydrogen chloride, for example.

In embodiments, the gas outlet may be connectable to means for removing a processed gas. For example, the gas outlet may be connectable to an extractor for removing processed gas.

A sieve plate may be located within the canister. The sieve plate may be configured to retain the particulate absorption media within the chamber. The sieve plate may be arranged proximal to the gas inlet or the gas outlet. The sieve plate may be configured to allow exhaust gases to flow through substantially unhindered. The sieve plate may comprise a mesh, wherein the holes in the mesh may be smaller than the minimum dimension of the absorption media to prevent the absorption media from passing through the sieve plate.

The canister may comprise an inlet port, wherein the inlet port is fluidly coupled to the gas inlet of the chamber. Additionally, the canister may comprise an outlet port, wherein the outlet port is fluidly coupled to the gas outlet of the chamber. In use, the inlet port of the canister may be fluidly coupled to an exhaust of a process tool. The process tool may be a tool used in the semiconductor manufacture process. The outlet port of the canister may be coupled to a further component of the exhaust gas abatement system. Alternatively, the outlet port may vent directly to the atmosphere.

The longitudinally extending wall of the chamber may be an outer wall of the canister. The wall may extend generally longitudinally between a first end and a second end of the chamber. The wall may be continuous, or it may be coupled by a weld and/or fastening means. Typically, the chamber may have generally circular cross-section. The diameter of the chamber may vary. In embodiments, the chamber may have a maximum diameter of about 600 mm or less, for example 560 mm. The thickness of the longitudinally extending wall may vary.

The present inventors performed an investigation into the degree of utilisation of the particulate absorption media within the dry absorber canisters of the prior art, i.e. canisters as shown in FIG. 1. Upon inspection of spent canisters, only about 35% by weight of the absorption media within the canister was deactivated. Therefore, about 65% by weight of the particulate absorption media within the canister was unused, but still useful. Moreover, it was noted that the deactivated absorption media was not evenly distributed throughout the chamber and instead was found in specific regions of the canister chamber.

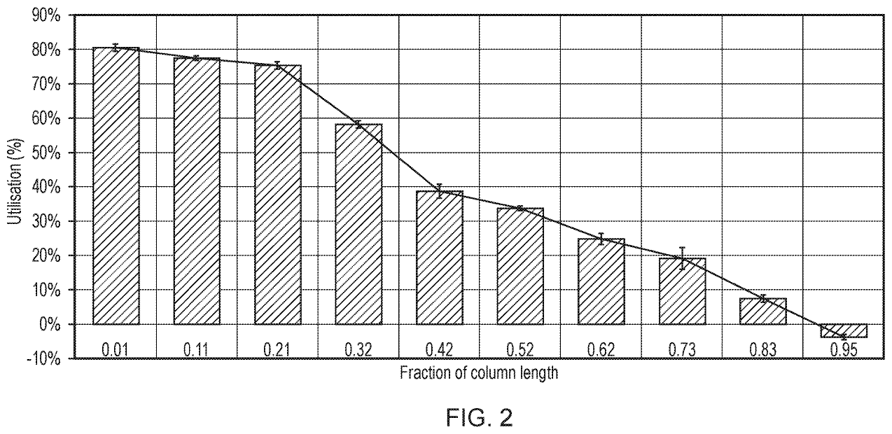

FIG. 2 shows a graph of utilisation of absorption media as a function of the fraction of column (i.e. chamber) length for a canister (1) of the prior art. The column length is the distance from the inlet to the outlet, as shown by “L” in FIG. 1. It was found that the particulate absorption media proximal to the inlet had a significantly higher utilisation than that proximal to the outlet. This indicates that there was non-uniform reaction of the absorption media throughout the canister, with the majority of the reaction between the exhaust gas and absorption media occurring proximal to the inlet. When the exhaust gases passed over the absorption media proximal to the outlet, the majority of the abatement reactions have already occurred and so the rate of absorption media deactivation is significantly less.

The time before replacement of canisters of the prior art may thus be determined by the rate of utilisation of absorption media proximal the chamber inlet, even when much of the absorption media proximal to the outlet of the chamber remains substantially unreacted. As all absorption media within the chamber is disposed of before refilling, unspent absorption media may be wasted.

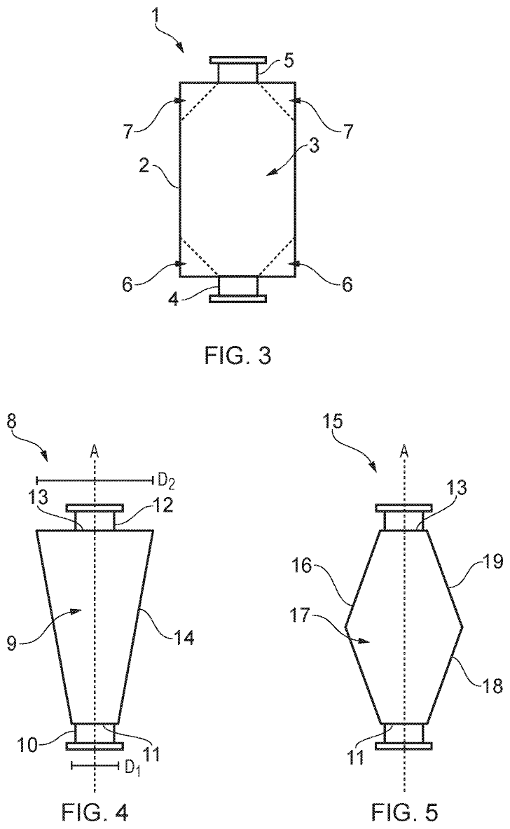

The present inventors also investigated the cross-sectional utilisation of absorption media within the canister. This is illustrated in FIG. 3, which shows that “dead zones” (6,7) were found in the corners of the cylindrical canisters (1) of the prior art. In these dead zones (6,7), the utilisation of the absorption media was significantly lower than that of the remainder of the canister. Particularly, dead zones (6) were present in the corners proximal to the inlet (4), and dead zones (7) are present in the corners proximal to the outlet (5). FIG. 3 is a two-dimensional illustration of the location of dead zones (6,7) within the canister (1), but the skilled person will appreciate that this is representative of the locations of the dead zones in three-dimensions.

Without wishing to be bound by theory, the non-uniformity of absorption media utilisation along the chamber length in prior art canisters may be due to a decrease in the concentration of reactants in the exhaust gas as it travels along the chamber length. This may be accompanied by a decrease in local temperature of the exhaust gas along the length of the canister. In canisters of the prior art, the longitudinal residence time of exhaust gases along the canister is substantially uniform, so the decrease in concentration of reactants causes a reduction in the utilisation of the absorption media along the chamber length. Furthermore, the presence of dead zones may be due to the non-uniform radial residence time of exhaust gases within the chamber. The residence time of exhaust gases may be greater towards the central axis of the chamber than proximal to the wall.

In canisters according to the invention, the cross-sectional area of the chamber varies between the first end and the second end, and the cross-sectional area increases from the gas inlet to a maximum cross-sectional area. Advantageously, the present inventors have found that by providing a non-uniform cross-sectional area between the first end and the second end, the uniformity of utilisation of absorption media throughout the chamber may be improved. Without wishing to be bound by theory, the greater the cross-sectional area of the chamber, the relatively longer the residence time of the exhaust gas over the absorption media in that region, and vice versa. The non-uniform residence time of exhaust gases may compensate for the reduction in concentration of reactants along the length of the chamber. Therefore, the present invention may improve the uniformity of absorption media utilisation within the chamber. Additionally, the time between services may be increased.

In embodiments, the cross-sectional area of the chamber may change, e.g. increase or decrease, substantially monotonically between a first end and a second end of the chamber. Typically, the chamber may taper along substantially the entire length of the chamber. Put differently, in embodiments, the chamber may be devoid of a segment including two or more fractions having a substantially continuous diameter.

The cross-sectional area of the chamber may be defined by the inwardly facing surface of the longitudinally extending wall.

The flow path of the exhaust gas may be from the gas inlet to the gas outlet. Typically, the gas inlet and/or gas outlet may be aligned on a central axis of the chamber. Preferably, the gas inlet and the gas outlet are coincident with the central axis of the chamber. Advantageously, this may allow a greater proportion of the absorption media to be directly in the flow path of the exhaust gas during operation. Aligning the gas inlet and/or gas outlet with the central axis of the chamber and varying the cross-sectional area of the chamber between a first end and a second end may reduce the likelihood of dead zones.

In embodiments, the maximum cross-sectional area may be at or adjacent to a second end of the chamber. In cylindrical canisters of the prior art, the absorption media at the second end of the chamber, i.e. proximal to the outlet, had a reduced utilisation in comparison to that at the first end of the chamber. Accordingly, providing the maximum cross-sectional area of the chamber at or adjacent to a second end of the chamber may increase the residence time of exhaust gases at the second end of the chamber relative to the residence time at first end of the chamber during use.

Typically, the cross-sectional area of the chamber decreases between the maximum cross-sectional area and the gas inlet. Preferably, the portion of the chamber between the gas inlet and the maximum cross-sectional area may be generally frustoconical. For the purposes of the present invention, frustoconical is defined as the shape of the non-planar portions of a frustum of a cone. The axial length of the frustoconical portion may be the same as the axial length of the chamber, or it may be less than the axial length of the chamber.

Advantageously, this arrangement may reduce the likelihood dead zones in the corners proximal to the gas inlet, as were found in cylindrical canisters of the prior art (see FIG. 3). Furthermore, the reduced cross-sectional area of the chamber towards the inlet may, in use, decrease the residence time of exhaust gases towards the gas inlet and thereby improve the uniformity of utilisation of the absorption media throughout the chamber.

Typically, the cross-sectional area of the chamber tapers towards the inlet. Preferably, a generally frustoconical portion of the chamber may extend to the gas inlet. Preferably, the cross-sectional area of the frustoconical portion of the chamber may be substantially equal to the cross-sectional area of the gas inlet where the frustoconical portion of the chamber meets the gas inlet. Advantageously, this may substantially avoid dead zones proximal to the gas inlet, and may reduce the residence time of exhaust gases proximal to the gas inlet.

Typically, a central axis of the chamber and a central axis of the frustoconical portion(s) of the chamber may be coaxial. Advantageously, this may improve the symmetry of the chamber, which may improve the uniformity of the utilisation of the absorption media throughout the dry absorber canister.

As described above, the present inventors have found that non-uniform reaction of the absorption media occurs in a conventional cylindrical canister of the prior art, with the majority of the reaction between the exhaust gas and absorption media occurring proximal to the inlet. Thus, in embodiments, the cross-sectional area of the chamber may be configured such that the degree of utilisation of absorption media is substantially constant along the length of the chamber.

In embodiments, the utilisation of absorption media due to the improvements described herein, as a function of the fraction of column length of the canister, may be no less than consistently about 20% between the inlet and outlet, preferably 40%, more preferably no less that 60%, for example no less than 70%. That is the usage percentages at each of the ten fractions of column length between the inlet and outlet illustrated in FIG. 2 are a minimum of 20%, preferably no less than 40%, more preferably no less than 60%, for example no less than 70%.

In other words, the cross-sectional area of the chamber may change, e.g. increase or decrease, along its length substantially proportionately to a change in utilisation of absorption media through the length of a theoretical cylindrical chamber having a substantially similar length and substantially similar maximum diameter.

For example, the cross-sectional area of the chamber may increase to a maximum cross-sectional area which corresponds to a fraction of a theoretical cylindrical chamber having a lowest or near lowest absorption media utilisation through the length of the theoretical cylindrical chamber.

Thus, the chamber may be configured, in particular the cross-section area of the chamber may be arranged, to substantially compensate for a loss in absorption media utilisation through the length of a corresponding theoretical cylindrical chamber having substantially the same length and substantially the same maximum diameter.

For example, if a theoretical cylindrical chamber, having substantially the same length and maximum diameter, and retaining equivalent absorption media, has a first fraction approximately 10% by distance through the length of the chamber with around 80% utilisation by weight, and a second fraction approximately 80% by distance through its length with around 10% utilisation by weight, the cross-sectional area of the chamber may increase proportionally, e.g. by approximately 70%, between corresponding column length fractions to compensate for the (otherwise) decrease in utilisation.

The skilled person will appreciate that different process gases and/or different absorption media may require different changes in cross-sectional area of the chamber to achieve the same effect.

Typically, the cross-sectional area of the chamber may decrease, i.e. taper, between the maximum cross-sectional area and the gas outlet. Preferably, the portion of the chamber between the maximum cross-sectional area and the gas outlet may be generally frustoconical.

Advantageously, this may reduce the likelihood dead zones in the corners proximal to the gas outlet, as were found in cylindrical canisters of the prior art (see FIG. 3). Preferably, a frustoconical portion may meet the gas outlet. Preferably, the smallest cross-sectional area of the frustoconical portion may be substantially equal to the cross-sectional area of the gas outlet where the frustoconical portion meets the gas outlet.

Preferably, the chamber may be at least partially defined by a frustoconical portion proximal to the gas inlet, wherein the cross-sectional area of this frustoconical portion decreases towards the gas inlet. The chamber may be defined by a further frustoconical portion proximal to the gas outlet, wherein the cross-sectional area of this frustoconical portion decreases towards the gas outlet. Most preferably, the chamber, and therefore the longitudinally extending wall, may define a conical bifrustum. Alternatively, the chamber, and therefore the longitudinally extending wall, may define a triangular, square, pentagonal, hexagonal, octagonal, or other bifrustum. In embodiments, the frustoconical portions may be immediately adjacent one another. In other words, the chamber may be entirely defined by the frustoconical portion proximal to the gas inlet and the frustoconical portion proximal to the gas outlet.

Preferably, in such embodiments, the axial length of the frustoconical portion proximal to the gas inlet may be greater than the axial length of the frustoconical portion proximal to the gas outlet. More preferably, the axial length of the frustoconical portion proximal to the gas inlet may be at least half the axial length of the chamber. Advantageously, this may further reduce the formation of dead zones, and may increase the residence time of exhaust gases towards the gas outlet. This arrangement may further improve uniformity of absorption media consumption throughout the chamber.

The skilled person will appreciate that improved uniformity of absorption media consumption throughout the chamber may depend on a number of factors. Such factors include, for example, the relative axial lengths and dimensions of the frustoconical portions proximal to the gas inlet and gas outlet, respectively, the composition of the exhaust gas being treated, and the absorption media selected.

In another aspect, the present invention provides a dry absorber canister for an exhaust gas abatement system. The canister comprises a hollow chamber configured to retain particulate absorption media. The chamber is defined by a wall, and had a gas inlet and a gas outlet. The chamber is configured to permit fluid to flow from the gas inlet to the gas outlet when retaining particulate absorption media. The chamber further contains a baffle configured to obscure at least a portion of the gas outlet from the gas inlet.

The dry absorber canister may preferably be for use in, or form part of, an exhaust gas abatement system for a semiconductor manufacturing process. The skilled person will understand that the particulate absorption media may be as defined in any other aspect or embodiment.

The canister may comprise an inlet port, wherein the inlet port is fluidly coupled to the gas inlet of the chamber. Additionally, the canister may comprise an outlet port, wherein the outlet port is fluidly coupled to the gas outlet of the chamber. In use, the inlet port of the canister may be fluidly coupled to an exhaust of a process tool. The process tool may be a tool used in the semiconductor manufacture process. The outlet port of the canister may be coupled to a further component of the exhaust gas abatement system. Alternatively, the outlet port may vent directly to the atmosphere.

The wall defining the chamber may preferably be an outer wall of the canister, preferably the wall may be a longitudinally extending wall. Typically, the wall may comprise sheet metal, shaped to define the chamber of the canister. The chamber defined by the wall may be substantially cylindrical. Alternatively, the wall may have another shape, such as a frustoconical shape or a conical bifrustum.

The baffle is configured to obscure at least a portion of the gas outlet from the gas inlet. Preferably, the baffle may be configured to obscure the entire gas outlet from the gas inlet. The term “obscure” may be defined as the baffle being positioned between the gas inlet and the gas outlet such that that there is no direct linear path for gas to flow between the gas inlet and the gas outlet, or portions thereof. The baffle may be configured to divert the direction of exhaust gas flow in use. Accordingly, gas flowing therebetween must flow around the baffle.

Advantageously, because the baffle prevents the exhaust gas from taking the most direct route between the gas inlet and the gas outlet, the diversion of the exhaust gas flow by the baffle may increase the residence time of the exhaust gas within the chamber. Furthermore, the baffle may improve the uniformity of the residence time of exhaust gas throughout the chamber, and/or may improve the uniformity of the utilisation of the absorption media.

For the avoidance of doubt, the arrangement of any embodiment of this aspect may be combined with any embodiment of the preceding aspect.

Typically, the gas inlet, the gas outlet, and the baffle may all be arranged along a central axis of the chamber. Advantageously, this arrangement of the gas inlet, the gas outlet, and the baffle may improve the uniformity of the utilisation of the absorption media within the chamber.

Preferably, the baffle is in the form of at least one screw thread configured to direct an exhaust gas flow from the gas inlet to the gas outlet. The screw thread may be positioned within the chamber. The, or each, screw thread may extend about a thread axis. The thread axis may be substantially coaxial with the central axis of the chamber. The screw thread may extend to the wall defining the chamber. The absorption media may be arranged in the volume defined by the turns of the screw thread. In embodiments, a said screw thread may arranged substantially as an Archimedean, i.e. arithmetic, screw.

Preferably, the, or each, screw thread may extend along at least half of the axial length of the chamber, more preferably at least 75% of the axial length of the chamber, most preferably substantially the entire axial length of the chamber.

Preferably, the screw thread may be a single-start, double-start, or four start screw thread. In embodiments comprising a multi-start screw thread (i.e. more than single-start), the chamber may have a plurality of gas inlets, each arranged to direct exhaust gas along a different start of the screw thread.

Preferably, the gas inlet(s) may be arranged proximal to the start(s) of the screw thread(s). Preferably, the gas outlet(s) may be arranged proximal to the end(s) of the screw thread(s). In use, the exhaust gas flow may enter the chamber via the gas inlet(s). The or each screw thread may define a spiral flow path for the exhaust gas through the chamber from the gas inlet(s) to the gas outlet(s). By directing the exhaust gas along a spiral flow path through the chamber, instances of dead zones may be reduced.

Advantageously, the screw thread may allow for greater uniformity of residence time of exhaust gases throughout the chamber. The screw thread may direct the gas flow through the chamber such that the flow path is longer than the direct distance between the inlet and outlet.

In some embodiments, the or each screw thread may extend from a central rod. Preferably, the rod is coaxial with the central axis of the chamber. Advantageously, the rod may support the or each screw thread. Additionally, or alternatively, the or each screw thread may extend to the wall of the chamber. Preferably the rod and screw threads are monolithic in construction.

Typically, the pitch of the or each screw thread may vary along its axial length. Preferably, the pitch of the or each screw thread may increase between the gas inlet and the gas outlet. The pitch of the screw thread may be defined as the axial distance along the thread axis of a single turn (i.e. a 360° turn) of the screw thread. Preferably, the screw thread comprises at least one full (i.e. 360° turn) within the axial length of the chamber, more preferably from about 2 to about 10 full turns. Typically, the larger the pitch of the screw thread, the longer the residence time of exhaust gas in this region, and vice versa. Accordingly, increasing the pitch of the screw thread towards the gas outlet may increase the residence time of exhaust gases through a previously under-utilised region of the chamber. This may advantageously improve the uniformity of utilisation of absorption media.

In another aspect, the present invention provides a dry absorber canister for an exhaust gas abatement system. The canister comprises a primary chamber having an inlet and an outlet. The primary chamber houses a secondary chamber configured to retain particulate absorption media. The secondary chamber comprises a plurality of ingress apertures configured to convey an exhaust gas flow from the canister inlet into the secondary chamber, and a plurality of egress apertures configured to convey the exhaust gas flow from the secondary chamber to the canister outlet.

In use, the plurality of ingress apertures may disperse the exhaust gas flow throughout the secondary chamber. The plurality of egress apertures may provide multiple locations for the exhaust gas flow to exit the secondary chamber. Advantageously, the arrangement of the invention improves dispersion of the exhaust gas flow within the secondary chamber, and thereby increases the uniformity of utilisation of the particulate absorption media within the secondary chamber.

The dry absorber canister may preferably be for use in an exhaust gas abatement system for a semiconductor manufacturing process. The particulate absorption media may be as defined in any other aspect or embodiment.

The inlet of the primary chamber may be connected to an inlet conduit of the canister. Alternatively, the inlet of the primary chamber may be an inlet port of the canister. The inlet of the primary chamber may be fluidly coupled to an exhaust of a process tool, preferably via the inlet conduit of the canister. The process tool may be a tool used in the semiconductor manufacture process. The outlet of the primary chamber may be connected to an outlet conduit of the canister. The outlet of the primary chamber may be fluidly coupled to a further component of the abatement apparatus, preferably via the outlet conduit. Alternatively, the outlet of the primary chamber may vent directly to the atmosphere.

The secondary chamber may comprise from about 2 to about 40 ingress apertures, preferably from about 2 to about 8 ingress apertures, for example, 4 ingress apertures. The ingress apertures may be generally circular, rectangular, oval, or other shape. The ingress apertures may be substantially evenly separated. Preferably, there may be from about 1 to about 40 egress apertures. The egress apertures may be generally circular, rectangular, oval, or other shape.

The dry absorber canister may further comprise a sieve plate. The sieve plate may be located within the canister and may be configured to retain the particulate absorption media within the secondary chamber. The sieve plate may be arranged proximal to the canister inlet or the canister outlet. The sieve plate may be configured to allow exhaust gases to flow through substantially unhindered. The sieve plate may comprise a mesh, wherein the holes in the mesh may be smaller than the minimum dimension of the absorption media. Advantageously, such a configuration may prevent the absorption media from passing through the sieve plate.

For the avoidance of doubt, in embodiments comprising a sieve plate, the sieve plate may not define the ingress apertures and/or egress apertures of the second chamber. The function of the sieve plate may be to retain the position of the particulate absorption media within the secondary chamber, whilst enabling exhaust gases to flow into/out of the secondary chamber substantially unhindered by the sieve plate. In contrast, the plurality of ingress apertures may be configured to disperse the exhaust gas flow throughout the secondary chamber. The plurality of egress apertures may be configured to provide multiple locations for the exhaust gas flow to exit the secondary chamber. Advantageously, such arrangement of the ingress and egress apertures may improve dispersion of the exhaust gas flow within the secondary chamber.

Preferably, the secondary chamber may be generally toroidal. The secondary chamber may be defined by a generally tubular inner wall arranged within a generally tubular outer wall. Preferably, the ingress apertures may be in the form of perforations in either the generally tubular inner wall or the generally tubular outer wall. Additionally, or alternatively, the egress apertures may be in the form of perforations in the other of the generally tubular inner wall or the generally tubular outer wall.

Preferably, there may be from about 2 to about 40 ingress apertures, for example 4 ingress apertures. The ingress apertures may be generally circular, rectangular, oval, or other shape of perforations. The ingress apertures may be substantially evenly spaced on the generally tubular inner wall or the generally tubular outer wall. The ingress apertures may be substantially evenly distributed on the generally tubular inner wall or generally tubular outer wall.

Preferably, there may be from about 1 to about 40 egress apertures, for example 4 egress apertures. The egress apertures may be generally circular, rectangular, oval, or other shape of perforations. The egress apertures may be substantially evenly distributed on the generally tubular inner wall or generally tubular outer wall.

Preferably, the ingress apertures may be in the form of perforations in the generally tubular inner wall, and the egress apertures may be in the form of perforations in the generally tubular outer wall.

The generally tubular inner wall may surround and be substantially parallel to the generally tubular outer wall. The particulate absorption media may be retained within the secondary chamber, such that the exhaust gas flow entering via the ingress apertures may pass over and/or through the absorption media as it travels to the egress apertures. Preferably, the particulate absorption media may be retained between the generally tubular inner wall and the generally tubular outer wall. Preferably, the dimensions of particulate absorption media, the ingress apertures, and the egress apertures may be selected such that the particulate absorption media cannot exit the secondary chamber via the ingress and/or egress apertures.

When in use, the exhaust gas may flow substantially radially inwardly or substantially radially outwardly between the ingress apertures and the egress apertures. Advantageously, such an arrangement and positioning of the ingress apertures and egress apertures may improve the dissipation of the exhaust gas through the secondary chamber, and thereby may improve uniformity of the utilisation of the absorption media throughout the secondary chamber.

Preferably, the generally toroidal secondary chamber may be a generally rectangular toroid. The generally tubular inner wall and generally tubular outer wall may be substantially parallel to the central axis of the generally rectangular toroid. Preferably, the generally toroidal secondary chamber has an axial length that is at least twice its maximum radius. The axial length may be measured along the central axis of the secondary chamber.

Preferably, the outer wall of the secondary chamber may be surrounded by a plenum configured to convey the exhaust gas flow from the secondary chamber to the canister outlet or from inlet to the secondary chamber. In such an embodiment, the outer wall of the secondary chamber may provide a baffle as described in an earlier aspect. Advantageously, the plenum may collect substantially all gas flow exiting the secondary chamber and direct it towards the canister outlet or direct all gas flow from the inlet towards the secondary chamber.

In another aspect, the present invention provides an exhaust gas abatement system. The exhaust gas abatement system comprises a dry absorber canister according to any preceding aspect or embodiment arranged therein. The dry absorber canister comprises particulate absorption media within the chamber. An inlet of the dry absorber canister is configured to be in fluid communication with an exhaust gas flow from a process tool. The particulate absorption media may be as defined elsewhere herein.

Typically, the process tool to which the exhaust gas abatement system is connected may be a process tool for the manufacture of semiconductors. For example, the exhaust gas abatement system may be connected to a Trias Semiconductor Processing Tool as produced by Tokyo Electron Limited (RTM).

The exhaust gas abatement system may be an iAreca as produced by Edwards Limited

Typically, the exhaust gas abatement system may comprise at least two dry absorber canisters according to any preceding aspect or embodiment arranged therein. At least one canister may be in fluid communication with the exhaust of the process tool, and at least one canister is not in fluid communication with the exhaust stream of the process tool.

Advantageously, having two dry absorber canisters within the system allows for the canisters to be immediately swapped when the absorption media within the canister in fluid communication with the exhaust stream is spent. This may reduce machine downtime, and allows the system to be in operation whilst spent absorption media is removed from this canister and replaced with new absorption media, before nesting the canister back within the system.

Preferably, the at least two dry absorber canisters may be embodiments described herein with at least a portion of the chamber being frustoconical. Preferably, the two dry absorber canisters may be substantially identical. More preferably, the canister not in fluid communication with the exhaust stream may be inverted in relation to the canister in fluid communication with the exhaust stream. Owing to the frustoconical wall portions, this may allow the canisters to be nested within the system and take up less space. This may be beneficial as the size of the system is limited and reducing the space taken up by the canisters may allow more space for other components of the exhaust gas abatement system.

In another aspect, the present invention provides a method of abating an exhaust gas flow from a process tool. The method comprises the steps of providing an exhaust gas abatement system according to the preceding aspect, and directing an exhaust gas flow through an inlet of the dry absorber canister.

The advantages associated with the method are as described in relation to preceding aspects or embodiments.

For the avoidance of doubt, all aspects and embodiments described hereinbefore may be combined mutatis mutandis.

The Summary is provided to introduce a selection of concepts in a simplified form that are further described in the Detailed Description. This summary is not intended to identify key features or essential features of the claimed subject matter, nor is it intended to be used as an aid in determining the scope of the claimed subject matter.

### BRIEF DESCRIPTION

Preferred features of the present invention will now be described, by way of example, with reference to the accompanying drawings, in which:

FIG. 1 shows a cross-sectional view of a typical dry absorber canister (1) of the prior art.

FIG. 2 shows a graph of utilisation of absorption media as a function of the fraction of column length for a canister of the prior art.

FIG. 3 shows a cross-sectional view of a typical dry absorber canister (1) of the prior art, indicating “dead zones” of low absorption media activity.

FIGS. 4-9 show cross-sectional views of dry absorber canisters in accordance with embodiments of the present invention.

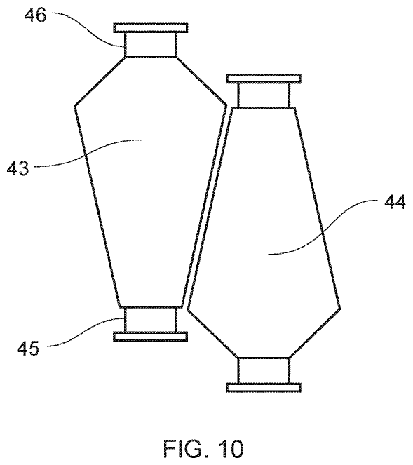

FIG. 10 shows a cross-sectional view of an exhaust gas abatement system in accordance with an embodiment of the present invention.

### DETAILED DESCRIPTION

FIG. 4 shows a cross-sectional view of a dry absorber canister (8) in accordance with an embodiment of the present invention. The canister (8) comprises a hollow chamber (9) configured to retain particulate absorption media (not shown). The canister (8) has an inlet conduit (10). The inlet conduit comprises a radially outwardly extending annular flange for coupling the canister to a further component when in use. The chamber (9) has a gas inlet (11) at a first end. The gas inlet (11) is directly connected to the inlet conduit (10). The canister (8) further comprises an outlet conduit (12). The outlet conduit (12) comprises a radially outwardly extending annular flange for coupling the canister to a further component when in use. The chamber (9) further has a gas outlet (13) at a second end, opposite the gas inlet (11). The gas outlet (13) is directly connected to the outlet conduit (12). The gas inlet (11) and gas outlet (13) are aligned with the central axis of the chamber (A).

The chamber is defined by a longitudinally extending wall (14). The cross-sectional area of the chamber (9), measured perpendicular to the central axis of the chamber (A), varies between the first end and the second end. The cross-sectional area of the chamber (9) is defined by the longitudinally extending wall (14). Specifically, in this embodiment, the cross-sectional area of the chamber (9) increases from the first end to the second end. The maximum cross-sectional area of the chamber (9) is at the second end, adjacent the gas outlet (13). The cross-sectional area of the chamber (9) has a tapered decrease between the second end and the gas inlet (11).

The wall (14) defining the chamber (9) is frustoconical in shape. The central axis of the frustoconical wall (14) is coaxial with the central axis of the chamber (A). The diameter of the frustoconical wall (14), and thereby the cross-sectional area, varies between the inlet (10) and the outlet (11) of the chamber (9). The cross-sectional area increases from the cross-sectional area proximal to the inlet (D1) to the cross-sectional area proximal to the outlet (D2). The rate of increase in cross-sectional area is substantially continuous between the gas inlet (11) and the gas outlet (13).

In use, an exhaust gas stream (not shown) enters the chamber (9) through the gas inlet (11). The exhaust gas stream passes over and/or between the absorption media, reacting therewith. The exhaust gas stream then exits the chamber (9) through the gas outlet (13). The increasing cross-sectional area of the chamber (9) between the first end and second end may reduce the residence time of the exhaust gas stream towards the first end of the chamber (9) relative to the residence time of the exhaust gas stream towards the second end of the chamber (9). Advantageously, this may improve the uniformity of absorption media utilisation throughout the chamber (9).

FIGS. 4 to 8 comprise some matching features, for which the same reference numerals will be used and the description shall not be repeated.

FIG. 5 shows a cross-sectional view of a dry absorber canister (15) in accordance with an alternative embodiment of the present invention. The chamber (17) of this illustrated embodiment is a bifrustum cone. The longitudinally extending wall (16) defining the chamber (17) comprises a first frustoconical portion (18) proximal to the gas inlet (11). The cross-sectional area of the chamber (17), measured perpendicular to the central axis (A), varies between the first end and the second end. The cross-sectional area of the first frustoconical portion (18) decreases from a maximum cross-sectional area to the cross-sectional area adjacent the gas inlet (11).

The longitudinally extending wall (16) defining the chamber (17) further comprises a second frustoconical portion (19) proximal to the gas outlet (13). The cross-sectional area of the second frustoconical portion (19) decreases from the maximum cross-sectional area to the gas outlet (13). In this embodiment, the maximum cross-sectional area of the chamber (17) is substantially equidistant from the gas inlet (11) and the gas outlet (13).

Advantageously, this embodiment may reduce the likelihood of “dead zones” proximal the gas inlet (11) and the gas outlet (13), as identified in the prior art canisters shown in FIG. 3.

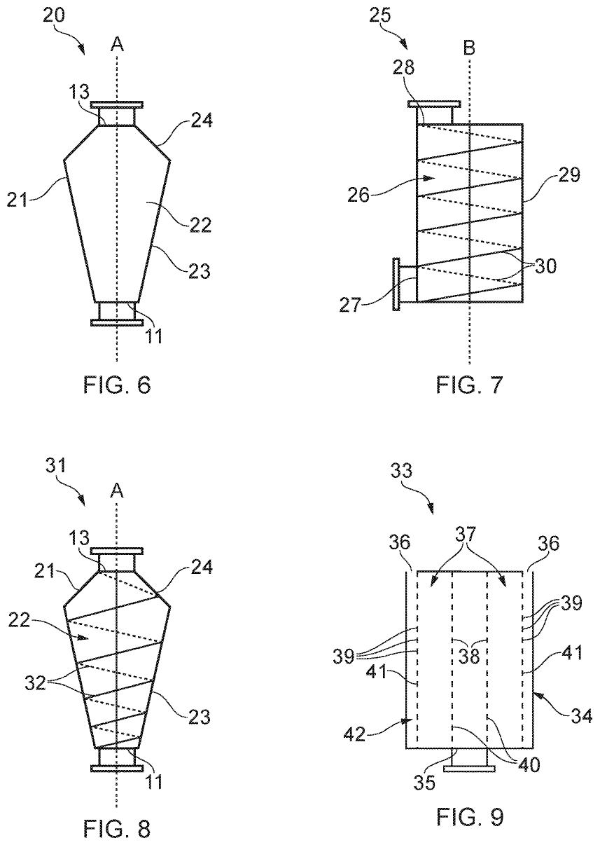

FIG. 6 shows a cross-sectional view of a dry absorber canister (20) in accordance with an alternative embodiment of the present invention. The chamber (22) of this illustrated embodiment is a bifrustum cone. Like the embodiment shown in FIG. 5, the longitudinally extending wall (21) defining the chamber (22) comprises a first frustoconical portion (23) proximal to the gas inlet (13), and a second frustoconical portion (24) proximal to the gas outlet (13). The cross-sectional area of the first frustoconical portion (23) decreases from the maximum cross-sectional area to the gas inlet (11). The cross-sectional area of the second frustoconical portion (24) decreases from the maximum cross-sectional area to the gas outlet (13).

The axial length of the first frustoconical portion (23) is greater than half of the axial length of the chamber (22). Indeed, in this embodiment, the axial length of the first frustoconical portion (23) is about 80% of the axial length of the chamber (22). Thus, the maximum cross-sectional area of the chamber (22) is closer to the gas outlet (13) than the gas inlet (11). This embodiment may be advantageous as the arrangement of the first and second frustoconical portions (23,24) may increase the residence time of exhaust gases towards the gas outlet (13), and thereby may improve the uniformity of the residence time of exhaust gases throughout the chamber (22). Additionally, this embodiment may reduce the likelihood of dead zones.

FIG. 7 shows a cross-sectional view of a dry absorber canister (25) in accordance with an alternative embodiment of the present invention. The canister (25) comprises a hollow chamber (26) configured to retain particulate absorption media (not shown). The chamber (26) has a gas inlet (27) and a gas outlet (28). The chamber (26) is defined by a wall (29). The chamber (26) is substantially cylindrical shape, and has a central axis (B).

The chamber (26) further comprises a baffle configured to obscure at least a portion of the outlet (28) from the inlet (27). The baffle comprises a screw thread (30) contained within the chamber (26). The screw thread (30) is configured to direct an exhaust gas flow (not shown) through the chamber (26) from the gas inlet (27) to the gas outlet (28), when the canister (25) is in use. The thread axis of the screw thread (30) is coaxial with the central axis (B) of the chamber (26). The screw thread (30) is directly connected to the wall (29). The particulate absorption media (not shown) are arranged between the turns of the screw thread (30). In this embodiment, the screw thread (30) is a single-start screw thread. In this embodiment, the pitch of the screw thread (30) is substantially uniform along the length of the screw thread (30), although the skilled person will appreciate that equally it may vary.

The gas inlet (27) is arranged generally perpendicular to the central axis (B) of the chamber (26). The gas inlet (27) is arranged proximal to the start of the screw thread (30). The gas outlet (28) is generally parallel to the central axis (B) of the chamber (26), but is not coaxial therewith. The gas outlet (28) is arranged proximal to the end of the screw thread (30). Accordingly, in use, the exhaust gas flow may enter the chamber (26) via the gas inlet (27) and be immediately directed into a flow path defined by the screw thread (30). The exhaust gas flow may then be directed by the screw thread (30) along a spiral flow path through the chamber (26) to the gas outlet (28). By directing the exhaust gas along a spiral flow path through the chamber (26), the likelihood of dead zones may be reduced.

FIG. 8 illustrates a cross-sectional view of a dry absorber canister (31) in accordance with an alternative embodiment of the present invention. The canister (31) has many features in common with the embodiment of FIG. 6, which will not be restated and for which the same reference numbers will be used.

The canister (31) further comprises a baffle configured to obscure at least a portion of the gas outlet (13) from the gas inlet (11). The baffle comprises a screw thread (32) contained within the chamber (22). The screw thread (32) is configured to direct an exhaust gas flow (not shown) through the chamber (22) from the gas inlet (11) to the gas outlet (13) when the canister (31) is in use. The thread axis of the screw thread (32) is coaxial with the central axis (A) of the chamber (22). The screw thread (32) is directly connected to the wall (21) that defines the chamber (22). The particulate absorption media are arranged between the turns of the screw thread (32).

The pitch of the screw thread (32) varies along its length. The pitch of the screw thread (32) increases between the gas inlet (11) and the gas outlet (13) of the chamber (22). The increase in the pitch of the screw thread (32) may correspond with a longer residence time of exhaust gas in the region with the larger pitch. Accordingly, the increase of the pitch of the screw thread (32) towards the gas outlet (13) may increase the residence time of exhaust gases towards the gas outlet (13). The pitch of the screw thread (32) and the diameter and length of the first and second frustoconical portions (23,24) of the chamber (22) have been selected such that they may provide an improved uniformity of the utilisation of absorption media. This arrangement may substantially avoid dead zones within the chamber (22).

FIG. 9 illustrates a cross-sectional view of a dry absorber canister (33) in accordance with an alternative embodiment according to the present invention. The canister (33) comprises a primary chamber (34) having an inlet (35) and an outlet (36). The primary chamber (34) houses a secondary chamber (37) configured to retain particulate absorption media (not shown).

The secondary chamber (37) comprises a plurality of ingress apertures (38) configured to convey an exhaust gas flow from the inlet (35) into the secondary chamber (37). The secondary chamber (37) further comprises a plurality of egress apertures (39) configured to convey the exhaust gas flow from the secondary chamber (37) to the outlet (36).

The secondary chamber (37) is generally toroidal. The secondary chamber (37) is a generally rectangular toroid. The secondary chamber (37) is defined by a generally tubular inner wall (40) arranged within a generally tubular outer wall (41). The plurality of ingress apertures (38) are in the form of perforations in the generally tubular inner wall (40). The plurality of egress apertures (39) are in the form of perforations in the generally tubular outer wall (41).

The inlet (36) may be arranged, in use, to be in fluid communication with an outlet of a process tool (not shown). When in use, an exhaust gas may flow substantially radially outwardly through the secondary chamber (37) between the ingress apertures (38) and the egress apertures (39). Advantageously, such an arrangement and positioning of the inlet apertures (38) and outlet apertures (39) may improve the uniformity of the utilisation of the absorption media in comparison to canisters of the prior art.

The generally tubular outer wall (41) of the secondary chamber (37) is surrounded by a plenum (42). The plenum (42) is configured to convey the exhaust gas flow from the secondary chamber (37) to the canister outlet (36). The exhaust gas flow exits the plenum (42) at an opposite end of the canister (33) to the inlet (35).

FIG. 10 shows the nesting arrangement of a pair of dry absorber canisters (43,44) in accordance with the present invention. The first canister (43) and second canister (44) are substantially identical, and may be in accordance with the embodiment of either FIG. 6 or 8.

The inlet port (45) of the first canister (43) is in fluid communication with the exhaust of a process tool (not shown). The exhaust gas is configured to flow through the first canister (43) and exit through the outlet port (46). The second canister (44) is not in fluid communication with the exhaust of the process tool.

The first and second canisters (43,44) each have chambers having frustoconical portions. Accordingly, the second canister (44) can be inverted in relation to the first canister (43) in the arrangement as shown, allowing the canisters (43,44) to be nested in close proximity. This may advantageously reduce the space required to arrange the canisters (43,44) within the housing of an exhaust gas abatement system (not shown). Furthermore, when the absorption media within the first canister (43) is spent, the first canister (43) can be removed and the second canister (44) can be inverted and be arranged in it's place. This may allow for treatment of the exhaust gas stream whilst the absorption media in the first canister (43) is replaced.

For the avoidance of doubt, features of any aspects or embodiments recited herein may be combined mutatis mutandis. It will be appreciated that various modifications may be made to the embodiments shown without departing from the spirit and scope of the invention as defined by the accompanying claims as interpreted under patent law.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A dry absorber canister for an exhaust gas abatement system, the canister comprising a hollow chamber configured to retain particulate absorption media;
the chamber having cross-sectional area defined by a longitudinally extending wall, and the chamber having a gas inlet at a first end and a gas outlet at a second end;
wherein the cross-sectional area of the chamber varies between the first end and the second end, and wherein the cross-sectional area of the chamber increases from the inlet to a maximum cross-sectional area.

2. The dry absorber canister according to claim 1, wherein the maximum cross-sectional area of the chamber is at or adjacent a second end of the chamber.

3. The dry absorber canister according to claim 1, wherein the cross-sectional area of the chamber decreases between the maximum cross-sectional area and the inlet, preferably wherein the portion of the chamber between the inlet and the maximum cross-sectional area is generally frustoconical.

4. The dry absorber canister according to claim 1, wherein the cross-sectional area of the chamber decreases between the maximum cross-sectional area and the outlet.

5. A dry absorber canister for an exhaust gas abatement system, the canister comprising a hollow chamber configured to retain particulate absorption media;
the chamber being defined by a wall, and having a gas inlet and gas outlet;
the chamber being configured to permit fluid to flow from the gas inlet to the gas outlet when retaining particulate absorption media, wherein the chamber further comprises a baffle configured to obscure at least a portion of the gas outlet from the gas inlet.

6. The dry absorber canister according to claim 5, wherein the gas inlet, the gas outlet, and the baffle are all arranged along a central axis of the chamber.

7. The dry absorber canister according to claim 5, wherein the baffle comprises at least one screw thread configured to direct an exhaust gas flow from the gas inlet to the gas outlet.

8. The dry absorber canister according to claim 7, wherein the or each screw thread extends about a thread axis, wherein the thread axis is substantially coaxial with the central axis of the chamber.

9. The dry absorber canister according to claim 7, wherein the pitch of the or each screw thread varies along its length, preferably wherein the pitch of the or each screw thread increases between the gas inlet and the gas outlet.

10. A dry absorber canister for an exhaust gas abatement system, the canister comprising a primary chamber having an inlet and an outlet, and housing a secondary chamber configured to retain particulate absorption media;
wherein the secondary chamber comprises a plurality of ingress apertures configured to convey an exhaust gas flow from the canister inlet into the secondary chamber, and a plurality of egress apertures configured to convey the exhaust gas flow from the secondary chamber to the canister outlet.

11. The dry absorber canister according to claim 10, comprising from about 2 to about 40 ingress apertures, preferably from about 2 to about 8 ingress apertures.

12. The dry absorber canister according to claim 10, wherein the secondary chamber is generally toroidal, defined by a generally tubular inner wall arranged within a generally tubular outer wall, wherein the ingress apertures are in the form of perforations in either the generally tubular inner wall or the generally tubular outer wall, and/or wherein the egress apertures are in the form of perforations in the other of the generally tubular inner wall or the generally tubular outer wall.

13. The dry absorber canister according to claim 12, wherein the outer wall of secondary chamber is surrounded by a plenum configured to convey the exhaust gas flow between the secondary chamber and the canister outlet or inlet.

14. An exhaust gas abatement system comprising:
a dry absorber canister according to claim 1 arranged therein;
wherein the dry absorber canister comprises particulate absorption media within the chamber, and wherein an inlet of the dry absorber canister is configured to be in fluid communication with an exhaust gas flow from a process tool.

15. A method of abating an exhaust gas flow from a process tool, comprising the steps of providing an exhaust gas abatement system according to claim 14, and directing an exhaust gas flow through an inlet of the dry absorber canister.

16. The dry absorber canister of claim 1 wherein the portion of the chamber between the maximum cross-sectional area and the outlet is generally frustoconical.

17. The dry absorber canister of claim 3 wherein the portion of the chamber between the maximum cross-sectional area and the outlet is generally frustoconical and the chamber is substantially entirely defined by the frustoconical portion proximal to the gas inlet and the frustoconical portion proximal to the gas outlet.
